(19) United States
(12) Patent Application Publication
(10) Pub. No.: US 2026/0203478 A1
(43) Pub. Date: Jul. 16, 2026

(54) OPTIMIZATION DESIGN DECISION METHODS FOR NON-UNIFORM INDOOR ENVIRONMENT OF LARGE-SPACE BUILDINGS BASED ON MULTIMODAL KNOWLEDGE GRAPH ENHANCED FOUNDATION MODEL

(71) Applicant: HARBIN INSTITUTE OF TECHNOLOGY, Harbin (CN)

(72) Inventors: Yunsong HAN, Harbin (CN); Xiran CUI, Harbin (CN); Cheng SUN, Harbin (CN); Biaoqing TAO, Harbin (CN); Hongji CUI, Harbin (CN); Qihui ZHANG, Harbin (CN)

(73) Assignee: HARBIN INSTITUTE OF TECHNOLOGY, Harbin (CN)

(21) Appl. No.: 19/413,121

(22) Filed: Dec. 9, 2025

Related U.S. Application Data
(63) Continuation-in-part of application No. PCT/CN2025/131666, filed on Oct. 31, 2025.

(30) Foreign Application Priority Data
Jan. 16, 2025 (CN) 202510069209.1

(51) Int. Cl. G06F 30/27; G06N 3/042

(52) U.S. Cl. CPC G06F 30/27; G06N 3/042

(57) ABSTRACT

Provided is an optimization design decision method for a non-uniform indoor environment of large-space buildings based on a multimodal knowledge graph enhanced foundation model. The optimization design decision method includes: obtaining multimodal data knowledge of a non-uniform indoor environment; fusing the multimodal data knowledge of the non-uniform indoor environment to construct a multimodal knowledge graph and a vector database of the non-uniform indoor environment; enhancing knowledge retrieval for an optimization design decision problem to construct a green performance optimization design model adapted to a typical non-uniform indoor environment engineering scenario; performing edge-cloud collaboration to flexibly process an optimization design problem, and achieving visual interaction of an optimization design result through a digital sandbox.

### CROSS-REFERENCE TO RELATED APPLICATIONS

This application is a Continuation-in-part of International Application No. PCT/CN2025/131666, filed on Oct. 31, 2025, which claims priority to the Chinese Patent Application No. 202510069209.1, filed on Jan. 16, 2025, the contents of each of which are hereby incorporated by reference.

### TECHNICAL FIELD

The present disclosure generally relates to the field of green building performance optimization design technology, and in particular to an optimization design decision method for a non-uniform indoor environment of large-space buildings based on a multimodal knowledge graph enhanced foundation model.

### BACKGROUND

With increasingly stringent requirements for building energy efficiency, the traditional optimization design decision method, which relies on performance simulation based on green performance data, has limitations in computational efficiency and cost. The method is difficult to handle multimodal building green performance data simultaneously and cannot effectively achieve multi-platform collaboration between design and simulation. As a result, energy-saving performance achieved through this method cannot meet new development demands and cannot effectively respond to the multidimensional requirements of buildings.

The indoor environment of a large-space building is non-uniform, and is affected by coupling of a plurality of factors, where the air flow process is complex, environmental parameters are variable, and problems such as heat accumulation and poor air flow are likely to occur. Different functional zones within the large-space building vary greatly in terms of ventilation, heat load, and occupant density. Some functional zones in the large-space building are prone to local occupant stagnation, which affects occupant comfort. Achieving effective temperature and humidity control, ventilation control, and occupant comfort regulation in the large-space buildings is a core issue in green performance optimization and decision-making for such buildings. The traditional optimization design decision method is difficult to adapt to specific temporal and spatial conditions and cannot effectively meet growing requirements for occupant comfort and building energy efficiency.

In recent years, multimodal large language models (MM-LLMs) have shown great potential in multimodal data fusion processing. With numerical, text, image, video, and audio modalities as inputs, the multimodal large language models are capable of understanding user requirements and generating decision-making suggestions and technical reports. However, the hallucination problem of the multimodal large language models limits the accuracy and reliability of engineering design applications. Using a knowledge graph-enhanced mode can effectively improve the hallucination problem. By relying on a knowledge graph that corresponds to specific engineering scenarios and by employing a retrieval-augmented generation model, design problems can be matched with triples in the knowledge graph, thereby enabling an intelligent question-answering process for the multimodal large language models.

### SUMMARY

One or more embodiments of the present disclosure provide an optimization design decision method for a non-uniform indoor environment of large-space buildings based on a multimodal knowledge graph enhanced foundation model, including:
S1: obtaining multimodal data knowledge of a non-uniform indoor environment;
the step S1 includes:
S11: collecting green performance data of the non-uniform indoor environment;
S12: generating an embedding representation of fused multimodal green performance information of the non-uniform indoor environment;
S13: extracting green performance data information of the non-uniform indoor environment to obtain extracted information;
S2: fusing the multimodal data knowledge of the non-uniform indoor environment to construct a multimodal knowledge graph and a vector database of the non-uniform indoor environment;
the step S2 includes:
S21: converting the extracted information into Resource Description Framework (RDF) triples;
S22: constructing the multimodal knowledge graph of the non-uniform indoor environment based on the RDF triples;
S23: determining an element of a typical non-uniform indoor environment engineering scenario;
S24: constructing and updating a corresponding multimodal knowledge graph and the vector database;
S3: enhancing knowledge retrieval for an optimization design decision problem to construct a green performance optimization design model adapted to the typical non-uniform indoor environment engineering scenario;
the step S3 includes:
S31: performing modular clustering on knowledge in the multimodal knowledge graph to obtain a structured subgraph;
S32: understanding a design problem and improving knowledge retrieval efficiency based on the structured subgraph;
S33: constructing the green performance optimization design model adapted to the typical non-uniform indoor environment engineering scenario;
S4: performing edge-cloud collaboration to flexibly process an optimization design problem and achieving visual interaction of an optimization design result through a digital sandbox;
the step S4 includes:
S41: constructing an edge-cloud collaborative architecture adapted to various typical non-uniform indoor environment engineering scenarios;
S42: constructing a digital twin model of a large-space building and displaying the optimization design result through the digital sandbox to achieve the visual interaction;
in the step S24, preprocessing extracted multimodal data of the non-uniform indoor environment; performing normalization and dimensionality reduction on numerical structured data of real-time monitoring of temperature, humidity, air velocity, illumination intensity, and energy consumption; generating an embedding vector for text data of project information, a user requirement, a design specification and standard, and a policy document based on a natural language processing model; extracting a feature vector from image data of a building photo, a rendering, a site plan, a floor plan, a section drawing, an elevation drawing, a detailed drawing, and a pseudo-color image of an optimization simulation result using a Convolutional Neural Network (CNN) model; and extracting a feature from a key frame of video data of a user behavior video and a building 3D model video using a 3D Convolutional Neural Network (C3D) model and an Long Short-Term Memory (LSTM) model;
in the step S24, standardizing a feature dimension of the green performance data based on the embedding vector; constructing a Hierarchical Navigable Small World (HNSW) vector index structure to improve a vector similarity search speed and provide support for matching semi-structured data in the multimodal knowledge graph, thereby accelerating an intelligent question-answering process for a user design problem;
in the step S24, for a green performance evaluation index of typical engineering scenarios, further determining influencing factors thereof, including equipment distribution, wall insulation performance, natural lighting, human flow, and dynamic load; and clarifying typical models or algorithm elements in computation or simulation, the typical models or algorithm elements including a Computational Fluid Dynamics (CFD) model, a solar analysis model, a dynamic energy consumption analysis model, a Predicted Mean Vote (PMV) model, a Predicted Percentage of Dissatisfied (PPD) model, an energy consumption optimization algorithm, and a zonal control algorithm; and
in the step S24, constructing a green performance profile of the non-uniform indoor environment for a specific large-space engineering scenario, and completing and updating a multimodal green performance database of the specific large-space engineering scenario.

One or more embodiments of the present disclosure provide an electronic device, including a memory and a processor, the memory stores a computer program, and the processor, when executing the computer program, implements the method described above.

One or more embodiments of the present disclosure provide a non-transitory computer-readable storage medium, configured to store computer instructions, when the computer instructions are executed by a processor, the method described above is implemented.

### BRIEF DESCRIPTION OF THE DRAWINGS

To more clearly illustrate the technical solutions in the embodiments of the present disclosure or the prior art, drawings used for describing the embodiments or the prior art are briefly introduced below. Obviously, the drawings in the following description are only some embodiments of the present disclosure. For those of ordinary skill in the art, other drawings can be obtained based on the provided drawings without any creative effort.

FIG. 1 is a flowchart illustrating an exemplary process for an optimization design decision method for a non-uniform indoor environment of large-space buildings based on a multimodal knowledge graph enhanced foundation model according to some embodiments of the present disclosure.

FIG. 2 is a schematic diagram illustrating an optimization design decision method for a non-uniform indoor environment of large-space buildings based on a multimodal knowledge graph enhanced foundation model according to some embodiments of the present disclosure.

### DETAILED DESCRIPTION

The technical solutions in the embodiments of the present disclosure are clearly and completely described below with reference to accompanying drawings in the embodiments of the present disclosure. Obviously, the described embodiments are only a part of the embodiments of the present disclosure, rather than all the embodiments. Based on the embodiments of the present disclosure, all other embodiments obtained by a person of ordinary skill in the art without creative efforts shall fall within the protection scope of the present disclosure.

For an optimization design decision of a non-uniform indoor environment of large-space buildings, traditional methods are mainly based on physical models and machine learning models, which have the following defects:
1. It is difficult to process and integrate multi-source and multimodal heterogeneous data of the non-uniform indoor environment. Traditional manners rely on static data and models, cannot provide feedback on real-time data, lack the ability to respond to emergencies, have slow design response and decision lag, and lack flexibility and adaptability.
2. It is difficult to accurately simulate and analyze green performance data affected by multi-factor coupling in the non-uniform indoor environment of the large-space buildings. The traditional method lacks knowledge reasoning ability, cannot effectively utilize the advantages of cloud computing power, has poor learning ability with respect to historical cases and similar schemes, and is difficult to provide a personalized design decision for specific scenarios, resulting in poor flexibility and scalability.

Therefore, an optimization design decision method for the non-uniform indoor environment of the large-space buildings based on a multimodal knowledge graph enhanced foundation model is provided in the present disclosure and can, during a design decision process, construct a green performance optimization design model adapted for a typical non-uniform indoor environment engineering scenario of the large-space buildings, understand an optimization design problem of the non-uniform indoor environment, and propose a method for optimization design decision, outputting numerical values such as a building form parameter, a space parameter, and a Heating, Ventilation, and Air Conditioning (HVAC) system parameter, and green performance image data of typical sections of the large-space building, etc. Based on this, a construction method of an enhanced foundation model empowered by knowledge representation is proposed. Based on an edge-cloud collaborative architecture, optimal allocation of computing resources is achieved, and a multimodal knowledge graph and a vector database are coordinated to improve knowledge retrieval and question-answering efficiency, reduce computing costs and time, and improve computing accuracy. In combination with a digital sandbox, visual interaction of an optimization design scheme is achieved.

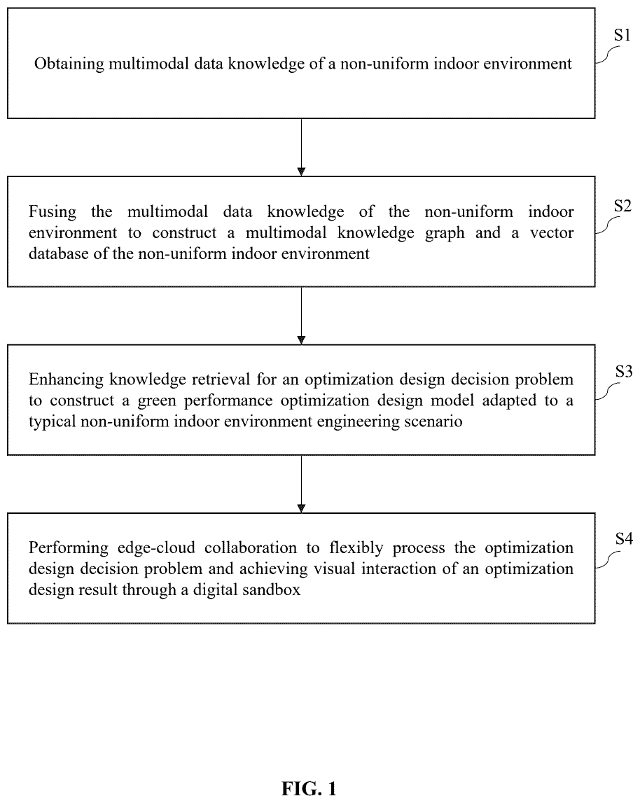

FIG. 1 is a flowchart illustrating an exemplary process for an optimization design decision method for a non-uniform indoor environment of large-space buildings based on a multimodal knowledge graph enhanced foundation model according to some embodiments of the present disclosure.

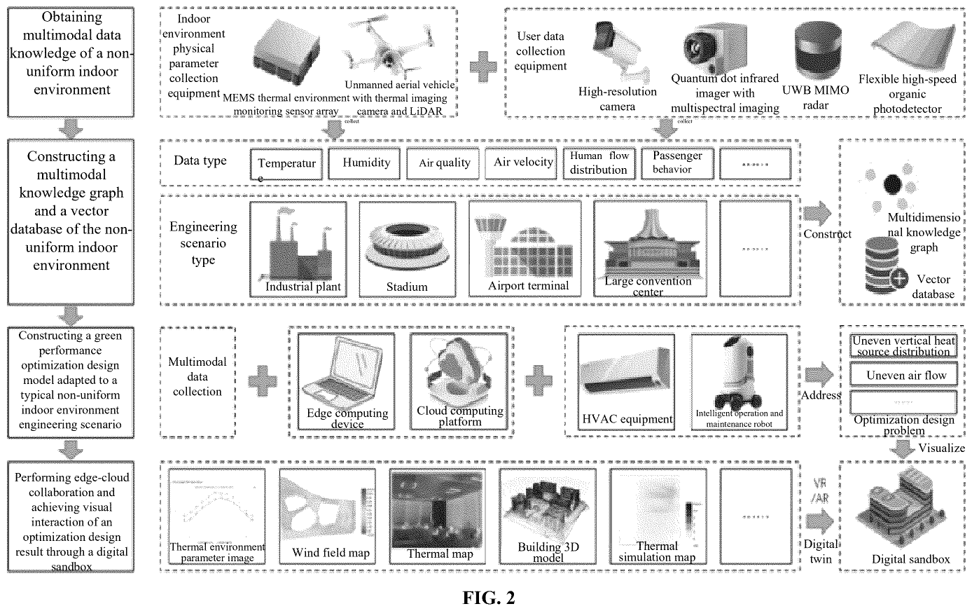

FIG. 2 is a schematic diagram illustrating an optimization design decision method for a non-uniform indoor environment of large-space buildings based on a multimodal knowledge graph enhanced foundation model according to some embodiments of the present disclosure. With reference to FIG. 1 to FIG. 2, the present disclosure proposes the optimization design decision method for the non-uniform indoor environment of the large-space buildings based on the multimodal knowledge graph enhanced foundation model. The method is executed by a processor and includes:
S1: obtaining multimodal data knowledge of the non-uniform indoor environment;
The non-uniform indoor environment refers to an environment in which indoor physical parameters are unevenly distributed. In some embodiments, the non-uniform indoor environment may mainly refer to an environment in the large-space building, for example, an airport terminal with uneven temperature and illuminance distribution, an industrial plant with uneven humidity and temperature distribution, etc.

Multimodal data refers to data of different modalities, which are obtained through different perception methods. Although the data are associated with a same engineering scenario, the data exhibit a certain degree of heterogeneity. For example, the data may be various data, such as numerical data (e.g., a temperature sensor reading), text data (e.g., a design specification document), image data (e.g., a building section drawing), video data (e.g., a surveillance video), etc.

In some embodiments, the multimodal data may be collected through indoor environment physical parameter collection equipment and user data collection equipment.

The indoor environment physical parameter collection equipment refers to equipment that collects physical parameters. For example, the indoor environment physical parameter may be a long-range-based micro-electro-mechanical systems (LoRa-based MEMS) thermal environment monitoring sensor array fixed on a building facade or installed on an intelligent cleaning or service robot, a thermal imaging camera and a multi-wavelength high-density point cloud light detection and ranging (LiDAR) carried on an unmanned aerial vehicle, etc.

The user data collection equipment refers to equipment that collects data related to a user. For example, the user data collection equipment may be a high-resolution camera, a quantum dot infrared imager with multispectral imaging, an ultra-wideband (UWB) multiple-input multiple-output (MIMO) radar, a flexible high-speed organic photodetector, etc.

The multimodal data knowledge refers to knowledge formed by multimodal data, which may be used for reasoning and decision-making.

In some embodiments, step S1 of obtaining the multimodal data knowledge of the non-uniform indoor environment may include:
S11: collecting green performance data of the non-uniform indoor environment.

The green performance data refers to data related to building green performance (e.g., building energy efficiency, environmental comfort, environmental quality, etc.). For example, the green performance data may be temperature, humidity, air velocity, illumination intensity, energy consumption, etc.

In some embodiments, a processor may, based on integrated platforms such as a Building Information Modeling (BIM) and an Internet of Things (IoT), dynamically acquire four types of data in the non-uniform indoor environment, including the numerical data, the text data, the image data, and video data. The processor may construct a green performance dataset for the non-uniform indoor environment based on the four types of data and determine a data modality type and corresponding data format requirements during a data parsing process.

BIM platform data is obtained through an industry foundation classes (IFC) format, and IoT platform data is obtained through a JavaScript object notation (JSON) format.

The numerical data is input through formats such as comma-separated values (CSV) and JSON, the text data is input through formats such as TXT, CSV, and JSON, the image data is input through formats such as JPEG and PNG, and the video data is input through formats such as MP4 and AVI.
S12. generating an embedding representation of fused multimodal green performance information of the non-uniform indoor environment.

The green performance information is the above green performance data.

The embedding representation refers to conversion of the multimodal data into a high-dimensional vector, enabling the data of different modalities to exhibit semantic correlations within a shared vector space, thereby facilitating model processing and multimodal data fusion.

In some embodiments, the processor may utilize cross-modal models such as contrastive language-image pre-training (CLIP) and multimodal versatile networks (MMV), based on an internal multimodal transformer architecture of the cross-modal models, to process green performance data of different modalities, convert the green performance data of different modalities into high-dimensional vectors that retain features of the multimodal data, and embed the high-dimensional vectors into a shared vector space.

In some embodiments of the present disclosure, information fusion and alignment can be achieved through the embedding representation, an association between building green performance data of different modalities, such as an association between images and text descriptions, are retained and strengthened to assist in understanding semantic relationships of the multimodal data, so that the model can consider information of multiple modalities simultaneously when processing multimodal tasks.
S13: extracting green performance data information of the non-uniform indoor environment

The green performance data information refers to structured information extracted from the green performance data, including entities, relations, and events.

In some embodiments, in the step S13, the extracting green performance data information may specifically include entity extraction, relation extraction, and event extraction. The entity extraction refers to applying a named entity recognition manner, including a Bidirectional Long Short-Term Memory-Conditional Random Field (BiLSTM-CRF) deep learning model, to extract a specific building green performance object or concept from an unstructured green performance dataset of the non-uniform indoor environment using context information. The relation extraction refers to using an Open Information extraction (OpenIE) or a Bidirectional Encoder Representations from Transformers (BERT) relation classification model or a dependency parsing manner to identify a relationship between the green performance entities of the non-uniform indoor environment. The event extraction refers to detecting spatio-temporal parameters of a plurality of the green performance entities of the non-uniform indoor environment through an Automatic Content Extraction (ACE) event extraction framework, and identifying an event trigger word and related information of a green performance event of the non-uniform indoor environment based on a deep learning model.

The entity extraction refers to extracting a building green performance entity from the green performance data. An entity refers to a specific object or concept with a specific semantics, including a building component, a building space, an operation device, a conceptual parameter, etc. For example, the entity may be an air conditioning system, a window-to-wall ratio, a west terminal waiting room, etc.

In some embodiments, the processor may apply a Named Entity Recognition (NER) manner, such as a deep learning model based on the BiLSTM-CRF, to extract a specific building green performance entity from an unstructured green performance dataset of the non-uniform indoor environment using the context information.

The relation extraction refers to extracting a semantic relationship between the building green performance entities from the green performance data. For example, the relation extraction may be that window-to-wall ratio affects energy consumption, air conditioning system controls temperature, etc.

In some embodiments, the processor may use the OpenIE or the BERT relation classification model or the dependency parsing manner to identify a relationship between the building green performance entities.

The event extraction refers to identifying the green performance event occurring in the green performance data. The green performance event refers to a phenomenon or behavior in which the green performance changes due to one or more green performance entities. For example, the green performance event may be a temperature exceedance event in the west terminal waiting room during a certain period in summer.

In some embodiments, the green performance event includes the spatio-temporal parameter and a trigger word of the green performance entity. The spatio-temporal parameters may include a time point and a spatial location where the green performance event occurs. The trigger word refers to a semantic word that characterizes an occurrence of a certain green performance event. For example, the trigger word may be “temperature rise”.

In some embodiments, the processor may follow the ACE event extraction framework to detect event arguments such as the spatio-temporal parameters of the green performance event, and identify the event trigger word and the related information of the green performance event of the non-uniform indoor environment based on the deep learning model, such as the BiLSTM-CRF and the BERT.

S2: fusing the multimodal data knowledge of the non-uniform indoor environment to construct the multimodal knowledge graph and the vector database of the non-uniform indoor environment.

The multimodal knowledge graph refers to a graph-structured knowledge representation, in which nodes represent entities, edges represent relationships, and embedding vectors of the multimodal data are fused. The multimodal knowledge graph is stored in a graph database for processing the semantic relations and structured knowledge. The vector database is used to store feature vectors of unstructured data and support similarity retrieval to quickly match embedding representations of the multimodal data.

In some embodiments, the processor may apply a multidimensional knowledge graph to expand knowledge representation of data such as temperature, humidity, noise level, air quality, air velocity, human flow distribution, and passenger behavior of the non-uniform indoor environment of the large-space building, and construct a multimodal knowledge graph and a vector database of green performance of the non-uniform indoor environment of the large-space building in combination with engineering scenario types such as an industrial plant, a stadium, the airport terminal, and a large convention center.

In some embodiments, step S2 of constructing the multimodal knowledge graph and the vector database includes:
S21: converting the extracted information into the RDF triples.

The RDF triple refers to a data model of “entity-relation-entity”, which is used to represent knowledge in a form of “subject-predicate-object”, such as air conditioning system-controls-temperature.

In some embodiments, the processor may convert the extracted green performance data information into the RDF triples in a plurality of manners. For example, the plurality of manners may be a template mapping manner, a manual annotation manner, etc.

In the step S21, the processor may convert the green performance data of the non-uniform indoor environment into an “entity-relation-entity” structured RDF triple through the RDFLib, and store the “entity-relation-entity” structured RDF triples in the graph database for subsequent processing, querying, and other operations.

S22: constructing the multimodal knowledge graph of the non-uniform indoor environment based on the RDF triples.

In the step S22, the processor may construct a relation graph between the entities by aligning extracted green performance entities and existing entities of the non-uniform indoor environment, and use a graph matching algorithm (a PageRank, a Random Walk, etc.) to link the entities, i.e., use node vector representations generated based on a random walk algorithm to link the entities, support global confidence evaluation of the entities, and then link the entities.

For records in the non-uniform indoor environment knowledge base (including the multimodal knowledge graph and the vector database) that point to the same entity, a clustering algorithm (e.g. a K-means, a DBSCAN, etc.) or a DeepWalk algorithm is used to merge the distances of entities and relationships embedding in a vector space, i.e., the entities and relationships are mapped into a low-dimensional vector space through the DeepWalk algorithm, and entities embedding in the vector space are grouped and merged through the clustering algorithms such as the K-means and the DBSCAN; a graph neural network, such as Graph Convolutional Networks (GCNs) and Relational Graph Convolutional Networks (RGCNs), are used to fuse relationships of the same entity from different data sources to obtain fused data; the fused data undergoes rule-based reasoning, and according to priority rules set based on data source reliability and timestamps, conflicting or contradictory knowledge obtained from different data sources is resolved, and new knowledge is derived; implicit relationships of the green performance data of the non-uniform indoor environment are mined for knowledge enhancement based on machine learning-based reasoning, such as a Graph Neural Network (GNN), improving the accuracy of information extraction and the reasoning capability of the knowledge graph. That is, the multimodal knowledge graph of the non-uniform indoor environment is constructed through a plurality of steps including aligning entities, merging the same entities, integrating multi-source relations, and performing knowledge reasoning.
S23: determining an element of a typical non-uniform indoor environment engineering scenario.

An element of an engineering scenario refers to an element that characterizes an environment feature of a large-space building space. The element of the engineering scenario may include an engineering scenario type and a green performance evaluation index.

The engineering scenario type refers to a specific space category of the large-space building. For example, the engineering scenario type may be the industrial plant, the stadium, the airport terminal, the large convention center, etc.

The green performance evaluation index refers to a parameter that characterizes the green performance of the non-uniform indoor environment, including electricity intensity, equipment energy consumption ratio, building energy consumption, indoor air quality, thermal comfort, lighting energy efficiency, etc.

In some embodiments, for large-space buildings with non-uniform indoor environment features, such as the industrial plants, the stadiums, the airport terminals, and the large convention centers, the processor may identify the engineering scenario type and extract the corresponding green performance evaluation index.
S24: constructing and updating the corresponding multimodal knowledge graph and the vector database.

In some embodiments, in the step S24, the processor may preprocess extracted multimodal data of the non-uniform indoor environment. Preprocessing includes normalization and dimensionality reduction on numerical structured data of real-time monitoring of the temperature, the humidity, the air velocity, the illumination intensity, and energy consumption (for example, converting sensor readings into values between 0 and 1 after the normalization; after the dimensionality reduction, only main feature values such as an average temperature and a fluctuation value are retained to form a numerical vector). The processor may generate the embedding vector for text data of project information, a user requirement, a design specification and standard, and a policy document based on a deep learning-based manner such as the BERT or a statistics-based manner such as a TF-IDF (for example, “the window-to-wall ratio shall not exceed 0.7” in a design specification document is converted into the high-dimensional vector). The processor may extract the feature vector from image data of a building photo, a rendering, a site plan, a floor plan, a section drawing, an elevation drawing, a detailed drawing, and a pseudo-color image of an optimization simulation result using a Convolutional Neural Network (CNN) model, such as a Residual Network (ResNet), (e.g., a feature vector representing a spatial layout and a thermal distribution in the drawing is extracted from the building section drawing through the ResNet model). The processor may extract a feature from a key frame of video data of a user behavior video and a building 3D model video using a 3D Convolutional Neural Network (C3D) model and an Long Short-Term Memory (LSTM) model (e.g., a feature vector representing a change in human flow density is generated from key frames corresponding to a personnel-intensive area in a user behavior video). That is, the multimodal data may be converted into a vector format through the preprocessing to facilitate subsequent embedding and storage. Subsequently, the numerical vector and the feature vector may be embedded into a same shared vector space as the embedding vectors.

In some embodiments, in the step S24, the processor may standardize a feature dimension of the green performance data based on the embedding vectors, and construct a Hierarchical Navigable Small World (HNSW) vector index structure to improve a vector similarity search speed and provide support for matching semi-structured data in the multimodal knowledge graph, thereby accelerating an intelligent question-answering process for a user design problem.

For example, a text vector (300-dimensional) and an image vector (2048-dimensional) are projected into a 512-dimensional shared space to standardize the feature dimension of the green performance data, i.e., the vector database stores a plurality of standardized embedding vectors. For converting the user design problem (e.g., “how to reduce energy consumption in a waiting area”) into a vector, a similar case in the vector database is quickly found through an HNSW index, in which a feature vector of the semi-structured data (e.g., sensor data in a JSON format) may also be indexed.

In some embodiments, in the step S24, the processor may, for a green performance evaluation index of a typical engineering scenario, further determine influencing factors thereof, including equipment distribution, wall insulation performance, natural lighting, human flow, and dynamic load; and the processor may clarify typical models or algorithm elements in computation or simulation, including a Computational Fluid Dynamics (CFD) model, a solar analysis model, a dynamic energy consumption analysis model, a Predicted Mean Vote (PMV) model, a Predicted Percentage of Dissatisfied (PPD) model, an energy consumption optimization algorithm, and a zonal control algorithm. The above influencing factors and typical models or algorithms may be added to the knowledge graph as the entities or the relations. For example, a “CFD model” entity is created in the knowledge graph and establishes a “used for simulation” relation with a “temperature distribution” entity.

In some embodiments, in the step S24, the processor may construct a green performance profile of the non-uniform indoor environment for a specific large-space engineering scenario, and complete and update a multimodal green performance database for the specific large-space engineering scenario.

Constructing the green performance profile refers to integrating all preprocessed data, influencing factors, and model results to form a structured summary. For example, a profile is created for the waiting area of the airport terminal, including average energy consumption, a temperature distribution map, a human flow pattern, etc.

When new data arrives (e.g., real-time sensor data or a new design specification), the above preprocessing steps are repeated to generate a new embedding vector, and the knowledge graph and the vector database are updated, including: through the steps S21-S22, converting a new entity, a new relation, and a new event into the RDF triple and adding the RDF triple to the graph database, i.e., updating the knowledge graph; preprocessing a newly generated feature vector as the new embedding vector, adding the new embedding vector to the vector database, and reconstructing the HNSW index to ensure retrieval efficiency. For example, in the airport terminal example, a real-time sensor shows that a temperature in a certain area increases, a temperature entity of the area in the knowledge graph is updated, and the feature vector is recalculated and stored in the vector database for subsequent retrieval.

In some embodiments, one entity in the knowledge graph may derive one or more vectors in the vector database, and one vector sample in the vector database may also be associated with one or more entities in the knowledge graph.

S3: enhancing knowledge retrieval for an optimization design decision problem to construct a green performance optimization design model adapted to the typical non-uniform indoor environment engineering scenario.

In some embodiments, the processor may, based on the multimodal knowledge graph and the vector database of the non-uniform indoor environment, construct the green performance optimization design model for the typical non-uniform indoor environment engineering scenario that collaborates with the indoor environment physical parameter collection equipment, the user data collection equipment, HVAC equipment, an intelligent operation and maintenance robot, an edge computing device, and a cloud computing platform.

In some embodiments, the step S3 includes:
S31: performing modular clustering on knowledge in the multimodal knowledge graph to obtain a structured subgraph.

The knowledge refers to a collection of all entities, relations, and attributes thereof stored in the multimodal knowledge graph, and the knowledge is carried by the RDF triple.

The modular clustering refers to a process of partitioning the multimodal knowledge graph into different structured subgraphs. The structured subgraph is a subset of the multimodal knowledge graph. Connections within each structured subgraph are dense, and connections between the different structured subgraphs are relatively sparse.

In some embodiments, in the step S31, the processor may identify groups of interconnected nodes in the knowledge graph through a community detection algorithm, and partition the multimodal knowledge graph into different communities; and identify and add missing relationships through a graph embedding algorithm (i.e., identify and add the missing relationships based on a knowledge completion model of the graph embedding algorithm), to enhance the completeness of the knowledge graph and support knowledge reasoning.

The community detection algorithm may be a Louvain algorithm, a Label Propagation algorithm, etc. The graph embedding algorithm may be Node2Vec, DeepWalk, etc. The processor may run the community detection algorithm, analyze a network structure of the entire multimodal knowledge graph, automatically partition the multimodal knowledge graph into a plurality of different communities according to a density of connections between the nodes, and identify and add the missing relationships through the graph embedding algorithm, to form a plurality of complete structured subgraphs, where the each structured subgraph represents a relatively independent engineering scenario or knowledge topic (e.g., “ventilation problem in an entrance hall”, “thermal comfort regulation in an office area”).

In a process of partitioning the structured subgraphs, the processor may add, to each embedding vector corresponding to related data in a structured subgraph, a label of the structured subgraph to which the embedding vector belongs. Through this step, the embedding vector in the vector database has the label of the structured subgraph to which the embedding vector belongs.
S32: understanding a design problem and improving knowledge retrieval efficiency based on the structured subgraph.

The design problem refers to a specific design requirement problem regarding the green performance in the non-uniform indoor environment, and is also referred to as an optimization design decision problem, the optimization design problem of the non-uniform indoor environment, or an optimization design task.

In some embodiments, in the step S32, the processor may, based on engineering scenario materials of a green performance optimization design including a design problem text, a real-scene photo, an engineering drawing such as the floor plan, the elevation drawing, or the section drawing input by a designer, understand a potential green performance hidden danger problem in a specific optimization design scenario, and understand the optimization design problem of the non-uniform indoor environment by considering indoor physical environmental parameters such as the temperature, the humidity, the illumination intensity, the air quality, an air pollutant concentration, and a ventilation volume, and taking into account limiting factors such as the equipment distribution, the wall insulation performance, the natural lighting, the human flow, and the dynamic load. Multidimensional features are analyzed through a clustering manner such as a hierarchical clustering manner and a k-means clustering manner, to summarize the typical non-uniform indoor environment engineering scenario pattern and perform hierarchical analysis on the communities. Algorithms such as Facebook AI Similarity Search (FAISS) and HNSW are used to assist vector retrieval, to improve the efficiency of machine learning tasks such as clustering and retrieval.

In some embodiments, the processor may use the graph embedding algorithm to compress overall structural information of the each structured subgraph into a subgraph vector representing a summary of the structured subgraph, convert the design problem into a problem vector through a natural language processing model, compare the problem vector with all subgraph vectors in the vector database for similarity, find one or more structured subgraphs corresponding to one or more subgraph vectors with a highest similarity, i.e., the structured subgraph(s) most relevant to the design problem; and then compare the problem vector with embedding vectors belonging to the most relevant structured subgraph(s) in the vector database for similarity, to determine an embedding vector with the highest similarity to the problem vector, i.e., match an embedding vector corresponding to green performance data of a historical reference case most similar to the design problem.
S33: constructing the green performance optimization design model adapted to the typical non-uniform indoor environment engineering scenario.

The green performance optimization design model refers to a model for optimizing a green performance design in the non-uniform indoor environment, which receives the design problem and related knowledge and outputs an optimization design scheme through internal computation.

In some embodiments, in the step S33, the processor may, based on the multimodal knowledge graph that fits the non-uniform indoor environment typical engineering scenarios on a cloud platform and based on a foundation model, train an enhanced foundation model empowered by knowledge representation of the green performance of the non-uniform indoor environment, leverage the computing power advantage of the cloud platform to handle coupling relationships between multimodal data involved in optimization design tasks of the non-uniform indoor environment, and empower a decision-making mode based on designers' subjective experience.

The foundation model refers to a base model based on an architecture such as a multimodal Transformer, the graph neural network, or a recurrent neural network. On the cloud platform and based on the foundation model, the enhanced foundation model is obtained through training using the multimodal knowledge graph and the vector database.

In some embodiments, an input of the green performance optimization design model includes the design problem of the user, the structured subgraph most relevant to the design problem determined in the step S32, an embedding vector corresponding to the historical reference case, an engineering scenario model, etc., and an output includes the numerical data and the image data, to provide design alternative solutions at levels such as a building form, a spatial layout, and an energy system design, respond to climate, environment, and a cultural requirement of the design task, and assist in proposing an optimization design decision.

In some embodiments, in the step S33, the green performance optimization design model may collaborate with various architectural design and building simulation software or platforms, process multimodal green performance data, and overcome limitations in computational efficiency or cost of specific algorithms or software tools.

In some embodiments, in the step S33, numerical data output by the green performance optimization design model includes the building form parameters, such as a building shape coefficient and a window-to-wall ratio, building space parameters, such as a bay width, a depth, and a floor height, the HVAC system parameters, such as equipment operation time and power consumption, etc.; and the image data output includes green performance predictions for a typical section of the large-space building, such as a temperature gradient prediction map, a flow field prediction map, and a glare simulation map of the large-space building.

In some embodiments, the green performance optimization design model for the typical non-uniform indoor environment engineering scenario includes a monitoring module, a retrieval module, a computing module, and an interaction module.

The monitoring module refers to a module configured to collect related data in the non-uniform indoor environment. In some embodiments, the monitoring module includes a physical parameter collection submodule and a user data collection submodule.

The physical parameter collection submodule is a module configured to collect a physical parameter. In some embodiments, the physical parameter collection submodule includes a LoRa-based MEMS thermal environment monitoring sensor array fixed on a building facade or installed on an intelligent cleaning or a service robot, to collect data such as the temperature, the humidity, the air quality, and the air velocity in the non-uniform indoor environment of the large-space building; a pipeline inspection robot and television imaging, to detect problems such as a crack, a blockage, and corrosion in a pipeline of the HVAC equipment; a high-mobility wheeled robot, to detect abnormal situations such as fire and smoke and monitor indoor safety; and a thermal imaging camera and a multi-wavelength high-density point cloud LiDAR mounted on an unmanned aerial vehicle, to monitor and analyze a thermal distribution situation of a building facade of the large-space building.

The user data collection submodule is a module configured to collect user-related data. In some embodiments, the user data collection submodule includes the high-resolution camera configured to recognize movement of a person based on a computer vision algorithm; the quantum dot infrared imager with multispectral imaging configured to monitor occupant density in a space in real time; the UWB MIMO radar configured to obtain a high-quality image of a respiratory signal in a multi-person scenario such as an entrance hall, a security check area, the waiting area, or a commercial area; and the flexible high-speed organic photodetector configured to collect physiological signals such as respiration, heart rate, and skin conductance of a user in the office area.

The retrieval module is a module configured to retrieve the structured subgraph. The retrieval module is based on a cross-modal alignment technology and utilizes data processing capabilities of the cloud platform to obtain a comprehensive understanding of a fusion feature of multimodal performance data and the design problem.

In some embodiments, the retrieval module, for the design problem input by the user and based on “knowledge retrieval” and “retrieval-augmented generation” technologies, vectorizes the design problem and performs similarity retrieval and comparison with the multimodal knowledge graph and the vector database; utilizes the multimodal knowledge graph to structure a semantic problem and determine a connection between the feature vector (i.e., the problem vector above) and an entity, a relation, and an attribute in the graph database; and utilizes the vector database to store the feature vector and find a most relevant match of the multimodal green performance data.

In some embodiments, the retrieval module may, based on knowledge such as a semantically similar case, enhance the capability of capturing a key problem in the design, generate a computation simulation instruction, and clarify a structured subgraph of the multimodal knowledge graph involved in the optimization design problem.

The computing module is a module configured to perform fusion computation and simulation analysis on the multimodal data of the non-uniform indoor environment. In some embodiments, the computing module cooperates with the retrieval module, based on a computation simulation instruction and the structured subgraph of the knowledge graph, integrates element features of a typical engineering scenario of the large-space building, utilizes lightweight and personalized models deployed on an edge side to achieve hierarchical lightweight decision-making, dynamically parses a green performance evaluation index of the non-uniform indoor environment, fuses multimodal data based on data collection, combines thermal simulation software to simulate heat transfer, thermal air flow, illumination intensity, etc., in a building, and performs CFD simulation of an air flow patterns, thermal distribution, and temperature gradients, responds to indoor environments under different seasons and different usage scenarios, analyzes and formulates optimization design decisions such as air conditioning design, a ventilation system layout, and heat source distribution, and outputs a building form, a space, and a HVAC system design corresponding to the optimization design decisions.

The interaction module is a module for visually displaying the optimization design scheme.

The optimization design scheme refers to a parameter set for performing optimization adjustment on the non-uniform indoor environment. In some embodiments, the interaction module may combine an output result of the computing module, construct a digital twin model of the large-space building, and combine VR and AR technology to project images of decision support data, such as temperature, humidity, air quality, air velocity, human flow distribution, and passenger behavior in typical plan, elevation, and section views onto a surface of the digital twin model; a designer manipulates a digital sandbox by wearing VR equipment or moving equipment components in a physical model; a cloud platform computes and analyzes parameter and energy consumption changes caused by the designer's operation in real time, and marks recommended equipment placement positions in alternative optimization design schemes for the designer in the digital twin model, to achieve visual comparison of the optimization design schemes and support real-time collaborative adjustment of the optimization design schemes by multiple personnel. The digital twin model refers to a simulation model that maps a state of the non-uniform indoor environment in a virtual space.

The recommended equipment placement position refers to a placement position of equipment in the non-uniform indoor environment.

In some embodiments, the digital twin model of the large-space building includes: outputting numerical and the image data such as temperature, humidity, air quality, and air velocity of the non-uniform indoor environment of the large-space building through the MEMS thermal environment monitoring sensor array; outputting human flow density image data through an infrared imager; outputting the numerical data such as the building form parameters including a building shape coefficient and a window-to-wall ratio, and the building space parameters including a bay width, a depth, and a floor height through LiDAR; outputting the image data such as a temperature gradient prediction map and a flow field prediction map for the large-space building and green performance predictions for typical sections of the large-space building through thermal simulation and CFD simulation; and data such as equipment operation time and power consumption of the HVAC equipment.
S4: performing edge-cloud collaboration to flexibly process the optimization design problem and achieving visual interaction of an optimization design result through a digital sandbox.

In some embodiments, the processor may construct a design decision cloud platform model for the non-uniform indoor environment, collaborate with a cloud-side model and an edge-side model, and flexibly process the optimization design problem.

The design decision cloud platform model is a comprehensive model that provides decision support for the green performance optimization design.

The cloud-side model is a data processing model deployed on cloud. The edge-side model is a data processing model deployed locally.

In some embodiments, the processor may, based on the green performance optimization design model for the non-uniform indoor environment, integrate a wind field map in plan, elevation, and section views of a large-space building collected by a MEMS thermal environment monitoring sensor array, a thermal map generated by capturing thermal radiation by an infrared imager, a building 3D model of a large-space building generated based on high-precision spatial data from LiDAR, and results from thermal simulation software and CFD simulation; construct a visual digital twin model of the non-uniform indoor environment of the large-space building based on the VR and AR technology; and achieve visual interaction for the designer through the digital sandbox for HVAC equipment placement position schemes in typical functional spaces such as an entrance hall, a security check area, the waiting area, a commercial area, and the office area.

In some embodiments, step S4 includes:
S41: constructing an edge-cloud collaborative architecture adapted to various typical non-uniform indoor environment engineering scenarios.

The edge-cloud collaborative architecture refers to a system architecture formed by combining an edge side and a cloud platform.

In the step S41, the processor may, based on a green performance optimization design scenario material of text and photo input by the designer, and targeting parameters of the temperature, the humidity, the air quality, and the air velocity, while considering constraints including a heat source distribution, an occupant distribution, and a usage scenario, understand the optimization design problem of the non-uniform indoor environment, and address a typical problem of optimization design for the non-uniform environment of the large-space building. That is, the processor may generate the optimization design scheme for the typical problem(s) of optimization design for the non-uniform environment of the large-space building.

In some embodiments of the present disclosure, based on an edge-cloud collaborative architecture, for complex green performance design problems of the non-uniform indoor environments, data processing capabilities of the enhanced foundation model empowered by cloud-side knowledge representation are utilized to obtain a comprehensive understanding of fusion features of the multimodal performance data. By collaborating the various architectural design and building simulation software or platforms, a green performance optimization design scheme for the non-uniform indoor environment of the large-space building can be developed, which overcomes limitations in computational efficiency or cost of specific algorithms or software tools.

In some embodiments, when the designer inputs an optimization design task instruction to a large model (also referred to as the design decision cloud platform model), the cloud-side model understands user requirements and sends a computation simulation instruction to the edge-side model to guide the edge-side model to perform simulation; the edge-side model, combined with the computation simulation instruction sent by the cloud-side model and an engineering scenario model or parameters of the non-uniform indoor environmental, performs green performance simulation optimization, and provides a simulation result and other decision basis for the cloud-side model.
S42: constructing a digital twin model of the large-space building and displaying the optimization design result through the digital sandbox to achieve the visual interaction.

In the step S42, the processor may construct the digital twin model of the large-space building; analyze parameter and energy consumption changes caused by modification of the optimization design scheme in real time through cloud computing, and combine with the VR and AR technology to achieve visualization comparison of the optimization design schemes, and support real-time collaborative adjustment of the optimization design schemes by multiple personnel.

In some embodiments, the processor, for the large-space buildings with the non-uniform indoor environment features, such as industrial plants, stadiums, the airport terminals, and large convention centers, integrates hardware device data from the LoRa-based MEMS thermal environment monitoring sensor array, cameras, and infrared imagers, analyzes time-varying trends of sensor data and peak periods of the human flow to analyze temporal and spatial features of engineering scenarios, analyzes historical data based on the deep learning model to identify and classify engineering scenario types, extracts the green performance evaluation index, determines influencing factors thereof and the typical models or algorithms in computation or simulation, completes and updates the multimodal green performance database, and stores the multimodal green performance database in the graph database. The processor, based on the deep learning algorithm for processing graph structured data, traverses interconnected green performance data, establishes a unified representation method for cross-scale multimodal information in the architectural field, such as text, raster images, 3D models, planar vectors, and building performance, converts input discrete data into high-dimensional vectors in a unified multimodal shared vector space, constructs the multimodal knowledge graph adapted to typical non-uniform indoor environment green performance optimization design engineering scenarios according to the engineering scenarios; and by generating the embedding vectors, standardizes feature dimensions of the green performance data, constructs an HNSW vector index structure, improves vector similarity search speed, constructs the vector database for non-uniform indoor environment green performance data, and provides support for matching the semi-structured data in the multimodal knowledge graph.

In some embodiments, an indoor environment monitoring sensor array includes a resistive flexible temperature sensor, a capacitive flexible humidity sensor, a tunable diode laser absorption spectroscopy sensor for monitoring gas concentrations such as CO₂, CO, and methane, an optical particle counter for monitoring suspended particles such as PM2.5 and PM10 in the air, and a particle image velocimeter for monitoring air velocity.

In some embodiments, the multimodal knowledge graph and the vector database support the multimodal data input including a numerical value (including indoor environment data, building form data, the green performance data, etc.), a text (project information, a user requirement, a design specification and standard, a policy document, etc.), an image (the building photo, the rendering, the site plan, the floor plan, the section drawing, the elevation drawings, the detailed drawing, the pseudo-color image of the optimization simulation result, etc.), and a video (a user behavior video, a building 3D model, etc.).

In some embodiments, the green performance evaluation index includes pollutant concentration, time and area proportion of indoor environmental parameters in an adaptive thermal comfort zone under natural ventilation or composite ventilation conditions in main functional rooms, temperature range of inner surfaces of external walls and roofs, average natural ventilation air change rate in main functional rooms under typical conditions in transition seasons, energy consumption of cold and heat sources, energy consumption of distribution systems, utilization rate of renewable energy, electricity intensity, etc.

In some embodiments, the typical problems of the indoor environment optimization design for the large-space buildings include uneven vertical heat source distribution in the large-space buildings, which requires balancing energy consumption and comfort, analyzing thermal convection motion, and determining local heating and fresh air system schemes; large temperature and humidity gradients caused by height differences, which require coordinating temperature and humidity and formulating zonal control design schemes for air conditioning systems; uneven air flow, which requires determining air stagnation zones, setting air circulation fans, and combining natural ventilation and mechanical ventilation to overcome spatial height differences and air flow stratification problems.

In some embodiments, the optimization design result includes the HVAC system parameter, and the HVAC system parameter includes a temperature and humidity regulation parameter, an air purification parameter, and a noise reduction parameter. The processor may, based on the optimization design result, determine an updated temperature and humidity regulation parameter, an updated air purification parameter, and an updated noise reduction parameter; control the HVAC equipment to operate according to the updated temperature and humidity regulation parameter, the updated air purification parameter, and the updated noise reduction parameter.

The optimization design result refers to an optimal parameter output by the green performance optimization design model, and is as same as the aforementioned optimization design scheme and optimization design decision.

More descriptions regarding the green performance optimization design model may be found in the related content of the step S3 above.

The HVAC system parameter refers to a parameter that controls operation of the HVAC equipment. The HVAC equipment refers to terminal equipment that implements heating, ventilation, and air conditioning functions, such as an air conditioning box, a fan coil unit, a fresh air unit, and a circulation fan.

The temperature and humidity regulation parameter may include a supply air temperature, a supply air humidity, etc., for operation of the HVAC equipment.

The air purification parameter may include a fresh air volume, an air circulation frequency per unit time, etc., of the HVAC equipment.

The noise reduction parameter may include a fan speed, an operation mode, etc., of the HVAC equipment.

In some embodiments, the processor may parse the updated temperature and humidity regulation parameter, the updated air purification parameter, and the updated noise reduction parameter from the numerical data output by the green performance optimization design model; the cloud-side model, through the edge-cloud collaborative architecture, sends the updated temperature and humidity regulation parameter, the updated air purification parameter, and the updated noise reduction parameter to the edge computing device, which converts the updated temperature and humidity regulation parameter, the updated air purification parameter, and the updated noise reduction parameter into control signals recognizable by the HVAC equipment, and controls the HVAC equipment to operate based on the control signals.

The edge computing device is a computing device deployed close to a data source end (such as a control cabinet, a gateway, or a high-performance server in a building).

In some embodiments of the present disclosure, converting the optimization design result into real-time responsive control signals can effectively cope with dynamic events such as changes in crowd numbers and sudden climate changes, and overcome defects of the decision lag in traditional design manners.

In some embodiments, a knowledge change monitoring module may be configured on the edge computing device, and green performance data of the HVAC equipment and sensors is continuously monitored based on the knowledge change monitoring module. In response to a variation amplitude of the green performance data exceeding a preset parameter threshold, a corresponding entity in the multimodal knowledge graph is updated according to a preset granularity based on the processor.

The knowledge change monitoring module refers to a module that monitors and analyzes data in real time.

The preset parameter threshold is a critical value that triggers update of the knowledge graph.

More descriptions regarding the green performance data may be found in the related content of the step S1.

In some embodiments, the preset parameter threshold may be a variation amplitude threshold. For example, a temperature variation amplitude is 2° C. When the variation amplitude of the green performance data exceeds a corresponding preset parameter threshold, the corresponding entity or entities in the multimodal knowledge graph are triggered to be updated according to the preset granularity.

In some embodiments, the preset parameter threshold may be determined in various manners. For example, the preset parameter threshold is determined manually based on historical experience.

In some embodiments, the preset parameter threshold may also be related to an information type, an information distribution location, and environment information of the green performance data.

The information type refers to a type of the green performance data. The information distribution location refers to a location of a green performance data collection point in a building space or in the knowledge graph. The environment information refers to external climate data that affects fluctuation of the green performance data. For example, the environment information may be seasons, weather, etc.

Different information types may correspond to different preset parameter thresholds. For example, a preset parameter threshold corresponding to temperature data is higher than a preset parameter threshold corresponding to humidity data. Different information distribution locations may correspond to different preset parameter thresholds. For example, a preset parameter threshold corresponding to a temperature sensor at an entrance hall with high human flow is greater than a preset parameter threshold corresponding to a temperature sensor in a relatively stable office area. Different environment information may correspond to different preset parameter thresholds. For example, a preset parameter threshold corresponding to energy consumption of HVAC equipment in hot weather is higher than a preset parameter threshold corresponding to energy consumption of the HVAC equipment in normal temperature weather.

In some embodiments, the knowledge change monitoring module is configured to construct a retrieval vector based on the information type, the information distribution location, and the environment information. The knowledge change monitoring module is configured to determine a target vector having a highest vector similarity to the retrieval vector and a corresponding reference parameter threshold by performing vector matching based on a preset parameter vector database. The knowledge change monitoring module is configured to determine a reference parameter threshold corresponding to the target vector as the preset parameter threshold.

The parameter vector database is constructed based on historical green performance data corresponding to a large amount of historical accidents. A reference vector is constructed based on a historical information type, a historical information distribution location, and historical environment information in the historical green performance data. The parameter vector database includes a plurality of reference vectors and reference parameter thresholds corresponding one-to-one to the reference vectors. The historical accident may be an accident in which further non-uniform problems, such as overheated spots, overcooled spots, or poor air circulation spots, occur in the large-space building due to failure to update the historical green performance data in a timely manner. The processor may determine a range of values of the historical green performance data corresponding to the large amount of historical accidents as the reference parameter threshold. The highest vector similarity may be represented by a minimum vector distance.

In some embodiments of the present disclosure, by introducing a dynamic preset parameter threshold, the system is enabled to distinguish normal fluctuations with valuable knowledge changes, thereby avoiding misjudging slight changes in wind speed or conventional fluctuations in outdoor temperature as knowledge requiring updates, and thus improving the robustness of the system.

The preset granularity refers to an operation scope for performing a knowledge update. The preset granularity may include a scope involved in the granularity, i.e., a corresponding entity to be updated in the multimodal knowledge graph and an attribute corresponding to the entity.

In some embodiments, the preset granularity may be determined in a plurality of manners. For example, the preset granularity is determined manually based on historical experience.

In some embodiments, the processor is further configured to determine the preset granularity based on the variation amplitude of the green performance data, the information type, and a node of a building graph structure.

For example, the processor is configured to obtain the variation amplitude of the green performance data and the information type based on the knowledge change monitoring module. The processor may update the green performance data on a corresponding node of the building graph structure. The processor may determine the preset granularity based on the building graph structure after updating the green performance data through a granularity model.

The building graph structure refers to a graph structure that characterizes partitions of the large-space building and relationships therebetween. The building graph structure includes a plurality of nodes and edges connecting the plurality of nodes. The node is a building sub-region (e.g., a building sub-region divided based on a building structure, a thermal zoning, a functional zoning, or an airflow organization characteristic). The edge is a spatial connectivity relationship between the nodes (e.g., a physically connected corridor, a ventilation duct, a door opening) and a physical coupling relationship (e.g., thermal radiation, air convection). More descriptions regarding the building graph structure may be found in the related descriptions below.

The granularity model is a model for determining the preset granularity. For example, the granularity model may be a GNN model.

In some embodiments, an input of the granularity model includes the building graph structure after updating the green performance data; an output of the granularity model includes the preset granularity.

In some embodiments, the granularity model is obtained by training a plurality of first training samples with first labels. The processor may input the plurality of first training samples with the first labels into an initial granularity model. The processor may construct a loss function based on the first labels and a result of the initial granularity model. The processor may iteratively update parameters of the initial granularity model based on the loss function through gradient descent or another manner. Training is completed when a preset condition is satisfied, and a trained granularity model is obtained. The preset condition may be convergence of the loss function, a count of iterations reaching a threshold, etc.

A first training sample may include a building graph structure of a sample. A first label may include an actual preset granularity in the training sample. The first label and the first training sample may be constructed based on the historical green performance data. For example, a plurality of historical actual building graph structures in the historical green performance data are determined as sample building graph structures. A node where a change in the historical green performance data occurs, a corresponding entity in the multimodal knowledge graph corresponding to the node, and an entity attribute corresponding to a changed historical green performance data are annotated as the preset granularity. If a change in a certain historical green performance data causes a change in other historical green performance data, a plurality of nodes where changes in the historical green performance data occur, a plurality of corresponding entities in the multimodal knowledge graph corresponding to the plurality of nodes, and a plurality of entity attributes corresponding to the plurality of changed historical green performance data are annotated as the preset granularity.

In some embodiments of the present disclosure, by determining the preset granularity through the granularity model, adaptive identification of an influence scope of a change in the green performance data is achieved, thereby avoiding subjectivity and instability caused by manually setting the granularity based on experience.

In some embodiments, in response to a variation amplitude of one or more green performance data exceeding the corresponding preset parameter threshold, the knowledge change monitoring module is configured to update a corresponding entity in the multimodal knowledge graph according to the preset granularity based on the processor. Merely by way of example, a fan speed of HVAC equipment No. 1 changes, and the variation amplitude exceeds the preset parameter threshold. The knowledge change monitoring module is configured to locate a corresponding entity of HVAC equipment No. 1 in the knowledge graph and update a fan speed attribute of the entity.

In some embodiments of the present disclosure, by performing real-time monitoring at an edge side, a problem of the decision lag in traditional operation and maintenance systems is overcome, and timeliness is improved. Meanwhile, by threshold filtering and minimum granularity update of the knowledge graph, communication bandwidth and processing load of a cloud platform are effectively reduced, a large amount of computing resources required for a full graph update is avoided, and stability and availability of the knowledge graph during continuous operation are ensured.

In some embodiments, for knowledge in the multimodal knowledge graph, the processor is further configured to determine a timeliness score of the knowledge based on an update frequency, an update time, and an information type of the knowledge.

The update frequency refers to a count of times the knowledge is updated per unit time. The update time refers to a duration from a latest update time point of the knowledge to a current time point.

The timeliness score refers to an indicator that characterizes an effective degree and a reference value of the knowledge at a current time point. The timeliness score may be a normalized value between [0, 1]. A larger value indicates a higher score. The higher score indicates that the knowledge is more effective and more worthy for reference.

In some embodiments, the processor is configured to determine the timeliness score in a plurality of manners. Merely by way of example, the timeliness score is determined by formula (1):

$$S = 100 \times ( \frac{{F}_{1}}{{F}_{2}} + \frac{{e}^{- Δ t}}{2} ) \qquad ( 1 )$$

S denotes the timeliness score of the knowledge. F₁ denotes the update frequency of the knowledge. F₂ denotes a baseline frequency of the knowledge. Δt denotes the update time of the knowledge. In some embodiments, the baseline frequency is set manually based on the information type of the knowledge.

In some embodiments of the present disclosure, by introducing the timeliness score to quantify timeliness, the system is enabled to maintain freshness and high credibility of the knowledge graph, thereby significantly improving an intelligence level and an adaptive level of a green performance optimization design task for the non-uniform indoor environment.

In some embodiments, the processor is further configured to determine the timeliness score of the knowledge through a scoring model built in a cloud platform based on the update frequency, the update time, the information type, and a node attribute of a building graph structure corresponding to the knowledge. The scoring model is the machine learning model.

The scoring model is a model for determining the timeliness score. The scoring model is a machine learning model, e.g., a graph neural network model.

In some embodiments, an input of the scoring model includes the update frequency, the update time, the information type of the knowledge, and a node attribute of a building graph structure corresponding to the knowledge; an output of the scoring model includes the timeliness score of the knowledge.

The node attribute of the building graph structure corresponding to the knowledge refers to an attribute of a node of the building graph structure to which a location of a source device of the knowledge belongs. For example, a piece of knowledge is data collected by a temperature sensor 1, and a location of the temperature sensor 1 is located at a node A (i.e., a building sub-area A) of the building graph structure, then a node attribute corresponding to the knowledge is the node attribute of the node A.

In some embodiments, the node attribute of the building graph structure includes a structural parameter, equipment information, an occupant density, and environment information of the node. The structural parameter may include a spatial dimension, a spatial shape, and a thermal parameter (e.g., a wall material, a window-to-wall ratio) of a sub-area of the large-space building. The equipment information refers to information of equipment (including the indoor environment physical parameter collection equipment and the user data collection equipment described above) disposed in the node or associated with the node. For example, the equipment information includes green performance data collected by the equipment and factory setting parameters of the equipment. The occupant density may be represented by a count of occupants per unit area. More descriptions regarding the environment information may be found in the related descriptions above.

In some embodiments, the scoring model may be obtained by training a plurality of second training samples with second labels.

The second training sample may include a sample update frequency, a sample update time, a sample information type, and a sample node attribute corresponding to sample knowledge. The second training sample may be constructed based on the historical data.

The second label may be a timeliness score corresponding to the sample knowledge. In some embodiments, the second label may be determined based on a degree of difference between a parameter in the large-space building and a preset ideal parameter after the sample knowledge is applied. The parameter in the large-space building after the sample knowledge is applied may refer to the HVAC system parameter in a historical optimization design result generated based on an updated knowledge graph after updating the knowledge graph with knowledge at a historical time point, which does not involve the building form parameter and the building spatial parameter. For details, refer to the related descriptions in the step S33. That is, the second label may characterize an optimization effect of the historical optimization design result generated using the sample knowledge, thereby reflecting a timeliness of the sample knowledge.

For example, the second label may be determined based on formula (2):

$$S = \frac{{\sum }_{j = 1}^{j = n} 1 - \frac{\vert {P}_{1 j} - {P}_{2 j} \vert}{{P}_{2 j}}}{n} \qquad ( 2 )$$

S denotes the timeliness score of the sample knowledge; P₁ⱼ denotes a parameter j (e.g., a supply air temperature in the historical optimization design result) in the large-space building after the sample knowledge is applied; P₂ⱼ denotes a preset ideal parameter j (e.g., a preset ideal supply air temperature); n denotes a total number of parameters. The preset ideal parameter may be preset based on historical experience.

For a training process of the scoring model, refer to the training process of the granularity model above, which is not repeated here.

In some embodiments of the present disclosure, determining the timeliness score through the machine learning model helps improve an accuracy and an efficiency of an overall design decision and reduces errors caused by outdated or irrelevant knowledge; by using the node attribute of the building graph structure as an input of the scoring model, an evaluation of the timeliness of the knowledge is ensured to be associated with physical spatial characteristics, making the timeliness management more aligned with an actual complex environment of the large-space building.

In some embodiments, the processor may store the knowledge in a vector form in the vector database as a knowledge vector; convert the optimization design problem into a problem vector and perform retrieval in the vector database; determine a target knowledge vector based on a weighted sum of a similarity score and the timeliness score; and determine the optimization design result based on the target knowledge vector.

The similarity score is an indicator characterizing a degree of similarity between vectors. In some embodiments, a higher similarity score indicates a higher similarity between the vectors. In some embodiments, the processor may, based on the problem vector, perform a retrieval in the vector database, identify the knowledge vector with the highest weighted sum of the timeliness score and the similarity score to the problem vector as the target knowledge vector, and input knowledge corresponding to the target knowledge vector into the green performance optimization design model to output the optimization design scheme. More descriptions regarding the green performance optimization design model may be found in the related descriptions above.

In some embodiments of the present disclosure, through a dual-scoring retrieval mechanism of the timeliness score and the similarity score, the optimization design scheme generated by the foundation model is ensured to be based on the latest and credible knowledge, greatly suppressing knowledge hallucination of traditional large models or erroneous decisions based on outdated information.

In some embodiments, the processor may modularize the large-space building into a plurality of nodes to establish the building graph structure; a node of the building graph structure is a building partition, a node attribute of the node includes a structural parameter, equipment information, an occupant density, and environment information of the node, and an edge of the building graph structure is a spatial connectivity relationship between the plurality of nodes; and perform modular monitoring and collection of the green performance data information of the non-uniform indoor environment based on the building graph structure.

Modularization refers to abstracting a continuous physical space in the large-space building into a discrete, computable unit. A modularization manner may include division based on the building structure, the thermal zone, the functional zone, or the airflow organization characteristic. More descriptions regarding the node, the edge, the node attribute, etc., may be found in the related descriptions above.

In some embodiments, the processor may perform the modular monitoring and collection of the green performance data information of the non-uniform indoor environment based on the plurality of nodes of the building graph structure.

In some embodiments of the present disclosure, by using the building graph structure to organize spatial relationships between the plurality of nodes, building information may be structured and topological, facilitating better capturing data changes in each partition and improving an accuracy and a pertinence of data collection.

In some embodiments, the processor, in response to the occupant density and/or the environment information triggering an update condition, updates the node attribute of a corresponding node and an equipment operation parameter of related equipment to obtain updated equipment operation parameter; controls the related equipment of the corresponding node to perform inspection on the HVAC equipment within a range of the corresponding node according to the updated equipment operation parameter, so as to collect green performance data of the HVAC equipment.

The update condition refers to a determination condition that triggers the node to update. For example, the update condition is triggered when a variation amplitude of the occupant density exceeds a first amplitude threshold (e.g., an increase in the occupant density exceeds 30%), a variation amplitude of the environment information exceeds a second amplitude threshold (e.g., a temperature decrease exceeds 50%), or a third-party weather change warning is received (e.g., a sunny-to-thunderstorm warning issued by a weather forecast). The first amplitude threshold and the second amplitude threshold are both preset manually.

In some embodiments, the edge computing device continuously collects the occupant density and the environment information, and in response to the occupant density and/or the environment information triggering the update condition, updates the occupant density and the environment information at a current time point to the node attribute of the corresponding node of the building graph structure.

The equipment operation parameter refers to an operation parameter of movable equipment or controllable equipment. For example, the equipment operation parameter includes a moving speed, an inspection path, a collection frequency, and a collection mode of a robot, an unmanned aerial vehicle, or a camera.

In some embodiments, the processor may update the equipment operation parameter through a preset algorithm. For example, the equipment operation parameter is updated by formula (3):

$${P}_{1} = {P}_{2} \times ( 1 + Δ A ) \qquad ( 3 )$$

P₁ denotes the updated equipment operation parameter; P₂ denotes the equipment operation parameter before update; ΔA denotes a variation amplitude of the node attribute, which may be represented by a variation amplitude of the occupant density of the node or a variation amplitude of the environment information. In some embodiments, the variation amplitude of the node attribute may also be determined manually. For example, when weather changes from sunny to rainy, or wind speed changes from level 3 to level 7, the variation amplitude of the node attribute is manually set to 1.

In some embodiments, the processor may transmit the updated equipment operation parameter to the equipment of the node through the edge-cloud collaborative architecture, and control the related equipment of the corresponding node according to the updated equipment operation parameter to perform the inspection on the HVAC equipment within the range of the corresponding node, so as to collect the green performance data of the HVAC equipment.

In some embodiments of the present disclosure, by dynamically updating the node attribute and the equipment operation parameter, the building environment system is enabled to make rapid and precise physical feedback to internal and external dynamic changes; by controlling the equipment operation parameter of an intelligent robot, a mobile sensor, etc., on-demand allocation of data collection is achieved; meanwhile, high-frequency and high-resolution collection is initiated only in areas requiring fine monitoring, avoiding energy waste and data redundancy caused by continuous high-intensity collection in all areas; in addition, the dynamic data collection provides real-time feedback with higher precision and higher spatio-temporal resolution for real-time regulation of the HVAC system parameter(s), ensuring an accuracy of the regulation parameters.

In some embodiments of the present disclosure, by knowledge representation of multimodal data of the non-uniform indoor environment of the large-space buildings, combined with a type of a specific application engineering scenario, the multimodal knowledge graph and the vector database of the green performance data of the non-uniform indoor environment are constructed, which can effectively represent and store the multimodal data. In a design decision process, the green performance optimization design model can understand the optimization design problem of the non-uniform indoor environment. Based on an edge-cloud collaborative architecture, optimal allocation of computing resources can be achieved, and the multimodal knowledge graph and the vector database are coordinated to improve knowledge retrieval and question-answering efficiency, reduce the computing cost and time, and improve computing accuracy. In addition, by combining with the digital sandbox, a visual interaction of the optimization design scheme can be achieved.

As shown in FIG. 1, this embodiment relates to an optimization design decision manner for a non-uniform indoor environment based on a multimodal knowledge graph enhanced foundation model, which is applied to large-space buildings, such as an airport terminal building (also referred to as the terminal building, or the terminal).

An indoor environment of the terminal building is complex, a human flow distribution is uneven, some areas have dense human flow and alternating functions, and a usage frequency and a demand change greatly. A temperature and humidity distribution of the indoor environment is uneven, and problems such as heat accumulation and poor air flow are prone to occur. In design, it is necessary to balance needs of energy saving and comfort on a basis of ensuring a passenger flow line, and achieve intelligent control.

An optimization design decision method for the non-uniform indoor environment based on a multimodal knowledge graph enhanced foundation model includes following steps, which are executed by a processor.
S1: obtaining multimodal data knowledge of the non-uniform indoor environment.

In this embodiment, the multimodal data knowledge of the non-uniform indoor environment is collected based on a BIM platform and an IoT platform.

Based on the BIM platform, geometric spatial data such as a building size, a location, a spatial layout, and a window-to-wall ratio, material physical properties such as a thermal conductivity coefficient, a thermal resistance, and an acoustic property of a building material, basic parameters and pipeline arrangements of a building HVAC system and other electrical equipment, energy monitoring data such as lighting and energy consumption, and building operation and maintenance data such as an equipment maintenance record and an operation schedule are collected. The building operation and maintenance data is the green performance data.

Based on the IoT platform, real-time dynamic data of the terminal building is collected. The real-time dynamic data includes indoor physical environmental parameters such as a temperature and humidity, an air quality, a noise level, and a work surface illuminance, energy consumption monitoring data such as a real-time total energy consumption of equipment operation of the HVAC system, or a real-time energy consumption of a specific area or specific equipment, and user-related data such as a human flow distribution and a passenger behavior. At the same time, dynamic changes of outdoor physical environmental parameters such as meteorological data, a wind speed, and a wind direction can be recorded, and project information, a user requirement, a design specification and standard, a policy document, etc., can be supplemented.

The geometric spatial data includes parameter numerical data, descriptive text data, and image data such as a building photo, a rendering, a site plan, a floor plan, a section drawing, an elevation drawing, and a detailed drawing. The material physical properties include numerical data and the descriptive text data. The energy monitoring data includes numerical data with time series information, the descriptive text data, the image data, such as a pseudo-color image and video data. The indoor physical environment data includes the numerical data with time series information and the image data, such as the pseudo-color image. The user-related data includes text data of a questionnaire survey, the image data, such as a photo, and video data, such as a behavior video.

Original data from different data sources is preprocessed, and structured information is extracted from the original data. For numerical data in a form such as a table, no processing is required. For the text data, semantic segmentation, part-of-speech tagging, etc., are implemented based on an NLP model or an LLM model.

For data of different modalities such as a numerical value, a text, an image, and a video, a multimodal Transformer deep learning architecture is used to embed the data into a vector space through different encoders. A self-attention mechanism is used to perform weight allocation between different modalities, to enhance an association understanding of data between the different modalities, for example, an understanding of a relationship between a section drawing of the terminal building and corresponding annotation text. A representation related to both modalities is generated, and time series information of dynamic data is retained.

For preprocessed data, entity data and relation data therein are extracted. A deep learning-based model such as BERT or ROBERTa is applied to identify a green performance entity. The green performance entity includes a green performance entity of the terminal building, which constitutes a subject or an object of an RDF triple. A relation classification model, such as an OpenIE model or a BERT model, or a dependency parsing manner is used to identify a relationship between the green performance entities of the indoor environment of the terminal building, and output a predicate of the RDF triple.

For event data involving a plurality of entities, attributes, and time series information, the processor, based on a deep learning model, such as a BiLSTM-CRF model or the BERT model, follows an ACE event extraction framework to mark an entity and a relationship, and identify information, such as an event trigger word and a role.
S2: fusing the multimodal data knowledge of the non-uniform indoor environment to construct a multimodal knowledge graph and a vector database of the non-uniform indoor environment.

An RDF toolkit RDFLib of Python is used to convert the green performance data of the indoor environment of the terminal building into an RDF triple of “entity-relation-entity”, and store the RDF triple in a graph database.

When new green performance knowledge of the indoor environment of the terminal building is extracted, the foregoing steps are repeated to extract entity, relation, and attribute information of the knowledge, a semantic representation is performed on a newly extracted green performance entity of the indoor environment of the terminal building by using context information and the green performance entity is embedded into a vector space, and entity linking is performed based on semantic similarity computation.

For text information, an entity may be matched based on a string similarity. For records in the graph database that may point to a same entity, an unsupervised clustering algorithm, such as K-means or DBSCAN, or a supervised machine learning method, such as logistic regression or random forest, is used to identify a duplicate entity, and a mode matching or a rule-based reasoning is used to determine whether relationships of different inputs are the same. A graph embedding manner such as a DeepWalk manner or a Node2Vec manner is used to embed the newly extracted green performance entity of the indoor environment of the terminal building and a relationship and an attribute thereof into the vector space, and a duplicate entity is identified and merged through distance computation. Based on this, a graph convolutional neural network or a relation attention network is used to fuse similar relationships from different sources. In a case that there is a conflict in an entity or an attribute, data is sorted based on factors, such as a set reliability of an information type of the terminal building, a timestamp, and a value range, and data with a highest priority is selected as credible data, and an ontology reasoning algorithm is used to verify that a logical constraint between the data satisfies an objective law and general architectural knowledge. Based on this, a GNN algorithm is used to further infer new knowledge.

For the engineering scenario of the terminal building, in view of characteristics such as a complex indoor environment and an uneven and time-varying human flow distribution, evaluation indexes include: a temperature, a relative humidity, an air velocity, and an air quality (a carbon dioxide concentration, a PM2.5 concentration) of different areas, height surfaces, and typical sections indoors, a work surface illuminance, an electricity intensity and an equipment energy consumption of the HVAC system and a lighting system in different areas, and a thermal comfort feeling of a user and a change in a human flow density.

A cold and heat load distribution of a space of the terminal building is complex, and is affected by a large-scale depth, a bay width, and a through height thereof, and influencing factors are different in different areas. Considered factors include: 1. whether an area is close to a curtain wall, where an area close to the curtain wall is greatly affected by factors such as outdoor environment solar radiation and infiltration wind, and an area far from the curtain wall is mainly affected by a human flow mobility and a density and an equipment heat dissipation; 2. a net height, where a temperature difference is large in an up-and-down through area due to hot air floating up; and 3. areas with different usage modes, where main areas of the terminal building include an entrance hall, a check-in area, a security check area, a waiting area, a baggage claim area, and a commercial area. The entrance hall has a strong human flow mobility, the check-in area has a characteristic of high-density and short-term gathering of occupants, the security check area and the baggage claim area have two modes of occupant retention and occupant movement, the waiting area has a long occupant retention time, and the commercial area has a large fluctuation in the occupant density.

The multimodal data of the non-uniform indoor environment is preprocessed, normalization and dimension reduction on real-time monitoring numerical structured data such as the temperature, the humidity, the air velocity, the illumination intensity are performed, and an energy consumption in different areas or heights and different usage scenarios, and a feature vector of the image data, such as the pseudo-color image of an optimization simulation result of a typical area section, and a user behavior video is extracted. Natural language processing on text data such as a common design specification and standard and a policy document of the terminal building is performed to generate an embedding vector. A CNN model, such as ResNet, is used to extract a feature vector from the image data, such as a specific building photo, the rendering, the site plan, the floor plan, the section drawing, the elevation drawing, and the detailed drawing of the terminal building, and a C3D network and an LSTM model is used to extract a feature from a key frame of a building 3D model. Based on this, an HNSW vector index structure and a vector database of the multimodal knowledge graph of the indoor environment of the terminal building are constructed, to assist in an optimization design decision for a green performance of the non-uniform indoor environment of the large-space building, such as an uneven vertical heat source distribution, a large temperature and humidity gradient, an uneven air flow, and a local glare or insufficient lighting.
S3: enhancing knowledge retrieval for an optimization design decision problem to construct a green performance optimization design model adapted to the typical non-uniform indoor environment engineering scenario.

For the knowledge graph of the green performance data of the terminal building, a community detection algorithm such as Louvain or Label Propagation is used to perform rough partitioning, to efficiently segment a community structure in a large-scale knowledge graph. A graph embedding algorithm such as the Node2Vec or the DeepWalk is used to perform vector representation on a node, to enhance the integrity of the knowledge graph and assist knowledge reasoning.

A clustering method, such as hierarchical clustering or k-means clustering, is used to summarize a typical engineering scenario mode of the terminal building, and an algorithm such as FAISS or HNSW is used to store an embedding community and entity in the vector database, to assist retrieval.

Based on green performance optimization design engineering scenario materials input in a question-answering process, such as a design problem text, a real-scene photo of a specific scenario of the terminal building, an engineering drawing of a plan, an elevation, and a section of the terminal building, and a typical section simulation diagram of the terminal building, a specific optimization design scenario type (the entrance hall, the check-in area, the security check area, the waiting area, the baggage claim area, or the commercial area) is determined, a potential green performance hidden danger problem of the specific optimization design scenario is understood, and a distribution of a temperature, a relative humidity, an air velocity, and an air quality (a carbon dioxide concentration, a PM2.5 concentration) of an area plane and a typical section related to the green performance hidden danger problem, an electricity intensity and an equipment energy consumption of an HVAC system and a lighting system in the area, and a thermal comfort feeling of a user and a change in a human flow density are searched. For the check-in area and the security check area, work surface illuminance information needs to be considered.

A CFD model, a solar analysis model, a dynamic energy consumption analysis model, a PMV model, a PPD model, an energy consumption optimization algorithm, a zonal control algorithm, etc., are collaboratively invoked to process a specific green performance simulation analysis problem, outdoor physical environment elements of a site and indoor physical environment data of a plurality of prediction models are coupled, to support a decision on a green performance problem of the terminal building and assist a designer in scheme comparison and selection. An alternative scheme such as an optimization suggestion on a local form or a spatial layout of the terminal building or an optimization design suggestion on an energy system or a technical platform, and the data that supports the alternative scheme, for example, the building form parameters such as a shape coefficient or a window-to-wall ratio of the terminal building, building spatial parameters such as a bay width or a depth of a specific area after an optimized spatial layout, HVAC system parameters such as an area equipment operation time and an electricity consumption of an existing scheme or a plurality of optimization schemes, and a building temperature gradient prediction diagram, a flow field prediction diagram, a glare simulation diagram, etc., in typical section view are output, to get rid of limitations of a specific algorithm or software tool in computing efficiency or cost.
S4: constructing a design decision cloud platform model for the non-uniform indoor environment, collaborating with a cloud-side model and an edge-side model, and flexibly processing an optimization design problem.

On a basis of a data set obtained by performing tasks such as design simulation and decision by using the green performance optimization design model adapted to the typical engineering scenario of the terminal building, a computing power advantage and a data processing capability of a cloud platform are brought into play, and based on a Mixtral8×78 large model, an enhanced foundation model empowered by a green performance knowledge representation of the terminal building is constructed, to comprehensively understand multimodal building information involved in the scenario of the terminal building, and better support a reasoning analysis capability of the green performance optimization design model for a complex problem.

Based on this, a collaborative analysis capability of the cloud-side enhanced foundation model and an edge-side green performance optimization design model is strengthened. Computing cost and time are reduced, and computing efficiency and accuracy are improved. When a designer inputs an optimization design task instruction to the large model (also referred to as the design decision cloud platform model), the cloud-side model understands the user requirement, and sends a simulation instruction to the edge-side model to instruct the edge-side model to perform simulation. The edge-side model performs green performance simulation optimization by combining the cloud-side instruction and an engineering scenario model or the non-uniform indoor environmental parameter, and outputs a simulation result to provide a decision basis for the cloud-side model.

For green performance data of the indoor environment of the terminal building that is updated in real time by IoT, the green performance data is collected in real time through an IoT sensor, and an analysis interval time is determined, data analysis is performed, and a corresponding decision reference scheme is provided according to a requirement of a collection and measurement accuracy. A designer or terminal operation and maintenance personnel compare or modify alternative solutions to formulate an operation plan for indoor physical environment regulation equipment. Based on excluding abnormal data, statistical parameters such as an average value and a standard deviation of the data in different time sequences are analyzed, and periodic law characteristics are summarized. When a deviation exceeds a preset critical value, the knowledge graph is updated.

In the process of solving a green performance optimization design problem, a green performance profile of the terminal indoor environment is constructed, and the multimodal green performance database of the terminal is supplemented and updated.
Some embodiments of the present disclosure further provide an electronic device, including a memory and a processor. The memory stores a computer program, and the processor, when executing the computer program, implements steps of the optimization design decision method for the non-uniform indoor environment of the large-space buildings based on the multimodal knowledge graph enhanced foundation model.
Some embodiments of the present disclosure further provide a computer-readable storage medium configured to store computer instructions. When the computer instructions are executed by a processor, steps of the optimization design decision method for the non-uniform indoor environment of the large-space buildings based on the multimodal knowledge graph enhanced foundation model are implemented.

The memory in the embodiments of the present disclosure may be a volatile memory or a non-volatile memory, or may include both a volatile memory and a non-volatile memory. The non-volatile memory may be a read only memory (ROM), a programmable read only memory (PROM), an erasable programmable read only memory (EPROM), an electrically erasable programmable read only memory (EEPROM), or a flash memory. The volatile memory may be a random access memory (RAM), which is used as an external cache. By way of exemplary but not restrictive description, many forms of RAM are available, such as a static random access memory (SRAM), a dynamic random access memory (DRAM), a synchronous dynamic random access memory (SDRAM), a double data rate synchronous dynamic random access memory (DDR SDRAM), an enhanced synchronous dynamic random access memory (ESDRAM), a synchlink dynamic random access memory (SLDRAM), and a direct rambus DRAM (DRDRAM). It should be noted that the memory described in the present disclosure is intended to include, but is not limited to, these and any other suitable types of memory.

In the foregoing embodiments, the embodiments may be implemented in whole or in part by software, hardware, firmware, or any combination thereof. When implemented by software, the embodiments may be implemented in whole or in part in a form of a computer program product. The computer program product includes one or more computer instructions. When the computer instructions are loaded and executed on a computer, the processes or functions according to the embodiments of the present disclosure are generated in whole or in part. The computer may be a general-purpose computer, a special-purpose computer, a computer network, or another programmable apparatus. The computer instructions may be stored in a computer-readable storage medium or transmitted from one computer-readable storage medium to another computer-readable storage medium. For example, the computer instructions may be transmitted from a website, computer, server, or data center to another website, computer, server, or data center in a wired manner (e.g., a coaxial cable, an optical fiber, or a digital subscriber line (DSL)) or a wireless manner (e.g., infrared, wireless, or microwave). The computer-readable storage medium may be any available medium that can be accessed by a computer or a data storage device, such as a server or a data center, integrating one or more available media. The available medium may be a magnetic medium (e.g., a floppy disk, a hard disk, or a magnetic tape), an optical medium (e.g., a high-density digital video disc (DVD)), or a semiconductor medium (e.g., a solid state disk (SSD)).

In an implementation process, the steps of the foregoing method may be completed by an integrated logic circuit of hardware in the processor or instructions in a form of software. The steps of the method disclosed in combination with the embodiments of the present disclosure may be directly performed by a hardware processor, or performed by a combination of hardware and software modules in the processor. The software module may be located in a mature storage medium in the art, such as a random access memory, a flash memory, a read only memory, a programmable read only memory, an electrically erasable programmable memory, or a register. The storage medium is located in the memory, and the processor reads information in the memory and completes the steps of the foregoing method in combination with hardware of the processor. To avoid repetition, details are not described herein again.

It should be noted that the processor in the embodiments of the present disclosure may be an integrated circuit chip and has a signal processing capability. In an implementation process, the steps in the foregoing method embodiments may be completed by an integrated logic circuit of hardware in the processor or instructions in a form of software. The processor may be a general-purpose processor, a digital signal processor (DSP), an application-specific integrated circuit (ASIC), a field programmable gate array (FPGA) or another programmable logic device, a discrete gate or a transistor logic device, or a discrete hardware component. The processor can implement or perform the methods, steps, and logical block diagrams disclosed in the embodiments of the present disclosure. The general-purpose processor may be a microprocessor, or the processor may be any conventional processor. The steps of the method disclosed in combination with the embodiments of the present disclosure may be directly performed by a hardware decoding processor, or performed by a combination of hardware and software modules in the decoding processor. The software module may be located in a mature storage medium in the art, such as a random access memory, a flash memory, a read only memory, a programmable read only memory, an electrically erasable programmable memory, or a register. The storage medium is located in the memory, and the processor reads information in the memory and completes the steps of the foregoing method in combination with hardware of the processor.

The optimization design decision method for the non-uniform indoor environment of the large-space buildings based on the multimodal knowledge graph enhanced foundation model proposed in the present disclosure is described in detail above. In the present disclosure, specific examples are used to describe the principles and implementation manners of the present disclosure. The description of the foregoing embodiments is only used to help understand the method and core ideas of the present disclosure. Meanwhile, a person of ordinary skill in the art may make modifications to the specific implementation manners and the disclosure scope according to the ideas of the present disclosure. In conclusion, the content of the present disclosure shall not be construed as a limitation to the present disclosure.

What is claimed is:

1. An optimization design decision method for a non-uniform indoor environment of large-space buildings based on a multimodal knowledge graph enhanced foundation model, comprising:
S1: obtaining multimodal data knowledge of a non-uniform indoor environment;
the step S1 includes:
S11: collecting green performance data of the non-uniform indoor environment;
S12: generating an embedding representation of fused multimodal green performance information of the non-uniform indoor environment;
S13: extracting green performance data information of the non-uniform indoor environment to obtain extracted information;
S2: fusing the multimodal data knowledge of the non-uniform indoor environment to construct a multimodal knowledge graph and a vector database of the non-uniform indoor environment;
the step S2 includes:
S21: converting the extracted information into Resource Description Framework (RDF) triples;
S22: constructing the multimodal knowledge graph of the non-uniform indoor environment based on the RDF triples;
S23: determining an element of a typical non-uniform indoor environment engineering scenario;
S24: constructing and updating a corresponding multimodal knowledge graph and the vector database;
S3: enhancing knowledge retrieval for an optimization design decision problem to construct a green performance optimization design model adapted to the typical non-uniform indoor environment engineering scenario;
the step S3 includes:
S31: performing modular clustering on knowledge in the multimodal knowledge graph to obtain a structured subgraph;
S32: understanding a design problem and improving knowledge retrieval efficiency based on the structured subgraph;
S33: constructing the green performance optimization design model adapted to the typical non-uniform indoor environment engineering scenario;
S4: performing edge-cloud collaboration to flexibly process the optimization design problem and achieving visual interaction of an optimization design result through a digital sandbox;
the step S4 includes:
S41: constructing an edge-cloud collaborative architecture adapted to various typical non-uniform indoor environment engineering scenarios;
S42: constructing a digital twin model of a large-space building and displaying the optimization design result through the digital sandbox to achieve the visual interaction;
in the step S24, preprocessing extracted multimodal data of the non-uniform indoor environment; performing normalization and dimensionality reduction on numerical structured data of real-time monitoring of temperature, humidity, air velocity, illumination intensity, and energy consumption; generating an embedding vector for text data of project information, a user requirement, a design specification and standard, and a policy document based on a natural language processing model; extracting a feature vector from image data of a building photo, a rendering, a site plan, a floor plan, a section drawing, an elevation drawing, a detailed drawing, and a pseudo-color image of an optimization simulation result using a Convolutional Neural Network (CNN) model; and extracting a feature from a key frame of video data of a user behavior video and a building 3D model video using a 3D Convolutional Neural Network (C3D) model and an Long Short-Term Memory (LSTM) model;
in the step S24, standardizing a feature dimension of the green performance data based on the embedding vector; constructing a Hierarchical Navigable Small World (HNSW) vector index structure to improve a vector similarity search speed and provide support for matching semi-structured data in the multimodal knowledge graph, thereby accelerating an intelligent question-answering process for a user design problem;
in the step S24, for a green performance evaluation index of the typical non-uniform indoor environment engineering scenario, further determining influencing factors thereof, including equipment distribution, wall insulation performance, natural lighting, human flow, and dynamic load; and clarifying typical models or algorithm elements in computation or simulation, the typical models or algorithm elements including a Computational Fluid Dynamics (CFD) model, a solar analysis model, a dynamic energy consumption analysis model, a Predicted Mean Vote (PMV) model, a Predicted Percentage of Dissatisfied (PPD) model, an energy consumption optimization algorithm, and a zonal control algorithm; and
in the step S24, constructing a green performance profile of the non-uniform indoor environment for a specific large-space engineering scenario, and completing and updating a multimodal green performance database of the specific large-space engineering scenario.

2. The optimization design decision method according to claim 1, wherein the optimization design result includes a Heating, Ventilation, and Air Conditioning (HVAC) system parameter, and the HVAC system parameter includes a temperature and humidity regulation parameter, an air purification parameter, and a noise reduction parameter;
the optimization design decision method further comprises:
determining an updated temperature and humidity regulation parameter, an updated air purification parameter, and an updated noise reduction parameter based on the optimization design result; and
controlling HVAC equipment to operate according to the updated temperature and humidity regulation parameter, the updated air purification parameter, and the updated noise reduction parameter.

3. The optimization design decision method according to claim 1, further comprising:
configuring a knowledge change monitoring module on an edge computing device, and continuously monitoring green performance data of HVAC equipment and a sensor based on the knowledge change monitoring module; and
in response to a variation amplitude of the green performance data exceeding a preset parameter threshold, updating a corresponding entity in the multimodal knowledge graph according to a preset granularity based on a processor.

4. The optimization design decision method according to claim 3, wherein the preset parameter threshold is related to an information type, an information distribution location, and environment information of the green performance data.

5. The optimization design decision method according to claim 3, further comprising:
determining the preset granularity based on the variation amplitude of the green performance data, an information type, and a node of a building graph structure.

6. The optimization design decision method according to claim 1, wherein further comprising:
for knowledge in the multimodal knowledge graph, determining a timeliness score of the knowledge based on an update frequency, an update time, and an information type of the knowledge.

7. The optimization design decision method according to claim 6, wherein the determining the timeliness score of the knowledge based on the update frequency, the update time, and the information type of the knowledge includes:
determining the timeliness score of the knowledge through a scoring model built in a cloud platform based on the update frequency, the update time, the information type of the knowledge, and a node attribute of a building graph structure corresponding to the knowledge, wherein the scoring model is a machine learning model.

8. The optimization design decision method according to claim 6, further comprising:
storing the knowledge in a vector form in the vector database as a knowledge vector;
converting the optimization design problem into a problem vector and performing retrieval in the vector database, and determining a target knowledge vector based on a weighted sum of a similarity score and the timeliness score; and
determining the optimization design result based on the target knowledge vector.

9. The optimization design decision method according to claim 1, further comprising:
modularizing the large-space building into a plurality of nodes to establish a building graph structure; wherein a node of the building graph structure is a building partition, a node attribute of the node includes a structural parameter, equipment information, an occupant density, and environment information of the node, and an edge of the building graph structure is a spatial connectivity relationship between the plurality of nodes; and
performing modular monitoring and collection of the green performance data information of the non-uniform indoor environment based on the building graph structure.

10. The optimization design decision method according to claim 9, further comprising:
in response to the occupant density and/or the environment information triggering an update condition, updating the node attribute of a corresponding node and an equipment operation parameter of related equipment to obtain an updated equipment operation parameter; and
controlling the related equipment of the corresponding node to perform inspection on HVAC equipment within a range of the corresponding node according to the updated equipment operation parameter, so as to collect green performance data of the HVAC equipment.

11. The optimization design decision method according to claim 1, wherein in the step S13, the extracting the green performance data information includes entity extraction, relation extraction, and event extraction; the entity extraction refers to applying a named entity recognition manner including a Bidirectional Long Short-Term Memory-Conditional Random Field (BiLSTM-CRF) deep learning model, to extract a specific building green performance object or concept from an unstructured green performance dataset of the non-uniform indoor environment using context information; the relation extraction refers to using an Open Information extraction (OpenIE) or Bidirectional Encoder Representations from Transformers (BERT) relation classification model or a dependency parsing manner to identify a relationship between a plurality of green performance entities of the non-uniform indoor environment; the event extraction refers to detecting spatio-temporal parameters of the plurality of green performance entities of the non-uniform indoor environment through an Automatic Content Extraction (ACE) event extraction framework, and identifying an event trigger word and related information of a green performance event of the non-uniform indoor environment based on a deep learning model.

12. The optimization design decision method according to claim 1, wherein in the step S21, the green performance data of the non-uniform indoor environment is converted into an “entity-relation-entity” structured RDF triple through a Python RDF toolkit Resource Description Framework Library (RDFLib), and the “entity-relation-entity” structured RDF triple is stored in a graph database for subsequent processing and query operations; in the step S22, by aligning extracted entities with existing entities of the non-uniform indoor environment, a relation graph between entities is constructed, and a graph matching algorithm is used to link the entities; for records in the non-uniform indoor environment knowledge base that point to a same entity, a clustering algorithm or a DeepWalk algorithm is used to merge distances of entities and relationships embedding in a vector space; an embedding model is used for relationship similarity computation, and a graph neural network is used to fuse relationships of the same entity from different data sources to obtain fused data; the fused data undergoes rule-based reasoning, and according to priority rules set based on data source reliability and timestamps, conflicting or contradictory knowledge obtained from different data sources is resolved, and new knowledge is derived; implicit relationships of green performance data of the non-uniform indoor environment are mined for knowledge enhancement based on machine learning-based reasoning, improving accuracy of information extraction and reasoning capability of the multimodal knowledge graph.

13. The optimization design decision method according to claim 1, wherein in the step S31, a community detection algorithm is used to identify groups of interconnected nodes, and the multimodal knowledge graph is partitioned into different communities; a graph embedding algorithm is used to identify and add missing relationships, enhancing completeness of the multimodal knowledge graph and supporting knowledge reasoning.

14. The optimization design decision method according to claim 1, wherein in the step S33, based on the multimodal knowledge graph that fits the typical non-uniform indoor environment engineering scenario, on a cloud platform, and based on a foundation model, an enhanced foundation model empowered by knowledge representation of green performance of the non-uniform indoor environment is trained, leveraging computing power advantage of the cloud platform to handle coupling relationships between multimodal data involved in optimization design tasks of the non-uniform indoor environment, and empowering a decision-making mode based on designers' subjective experience.

15. The optimization design decision method according to claim 1, wherein
in the step S41, based on a green performance optimization design scenario material of text and photo input by a designer, and targeting parameters of the temperature, the humidity, air quality, and the air velocity, while considering constraints including a heat source distribution, an occupant distribution, and a usage scenario, an optimization design problem of the non-uniform indoor environment is understood, and a typical problem of optimization design for the non-uniform environment of the large-space building are addressed;
in the step S41, based on an edge-cloud collaborative architecture, for a complex green performance design decision problem of the non-uniform indoor environment, the data processing capability of the enhanced foundation model empowered by cloud-side knowledge representation is utilized to obtain a comprehensive understanding of a fusion feature of multimodal performance data; various architectural design and building simulation software or platforms are coordinated to formulate a green performance optimization design decision for the non-uniform indoor environment of the large-space building, overcoming limitations in computational efficiency or cost of specific algorithms or software tools; and
in the step S41, when the designer inputs an optimization design task instruction to a large model, a cloud-side model understands the user requirement and issues a simulation instruction to an edge-side model, guiding the edge-side model to perform simulation; the edge-side model, combining the cloud-side instruction and an engineering scenario model or parameters of the non-uniform indoor environment, performs green performance simulation optimization and outputs a simulation result, providing a decision basis for the cloud-side model.

16. The optimization design decision method according to claim 1, wherein in the step S42, the digital twin model of the large-space building is constructed; through cloud computing, parameter and energy consumption changes caused by modifications of an optimization design scheme are analyzed in real time, and combined with VR and AR technology, visualization comparison of the optimization design scheme is realized, and real-time collaborative adjustment of the optimization design scheme by multiple personnel is supported.

17. An electronic device, comprising a memory and a processor, wherein the memory stores a computer program, and wherein the processor, when executing the computer program, implements the optimization design decision method according to claim 1.

18. A non-transitory computer-readable storage medium, configured to store computer instructions, wherein when the computer instructions are executed by a processor, the optimization design decision method according to claim 1 is implemented.
